(19) United States
(12) Patent Application Publication
(10) Pub. No.: US 2025/0238561 A1
(43) Pub. Date: Jul. 24, 2025

(54) VIRTUAL PRODUCT BUILDING PLATFORM

(71) Applicant: Barefoot Citizens IP Pty Ltd, Bulimba (AU)

(72) Inventors: Simon James DOBLE, Brisbane (AU); Joanna Lesley CANTWELL, Melbourne (AU)

(73) Assignee: Barefoot Citizens IP Pty Ltd, Bulimba (AU)

(21) Appl. No.: 18/416,198

(22) Filed: Jan. 18, 2024

(51) Int. Cl. G06F 30/12

(52) U.S. Cl. CPC G06F 30/12

(57) ABSTRACT

Disclosed herein are systems, methods, and computer-readable storage media for generating a virtual product that corresponds to an actual product that can be built. The computerized system can graphically display a canvas including parts of the virtual product and one or more tools to build the virtual product, each of the parts and the tools corresponding to actual parts and tools used to build the actual product; detecting one or more positional user inputs for positioning the parts on the canvas relative to one another; detecting one or more fastening user inputs for attaching parts to one another using the tools and fasteners; and displaying a generated virtual product on the canvas that corresponds to the actual product that can be built. In some examples, when the virtual product is generated, the computerized system can cause the actual product corresponding to the virtual product to be built.

### FIELD

This disclosure relates generally to virtual platforms, and more specifically to virtual platforms for building virtual products that correspond to actual products that can be built.

### BACKGROUND

Developing countries and economically challenged areas can be scarce in necessary items ranging from consumable products (e.g., food, personal care products, etc.) to textiles (e.g., clothing, bedding, etc.) to energy resources (e.g., electronics, lighting systems, and other power sources). The lack of energy resources is otherwise known as energy poverty. Energy poverty condemns billions of people to darkness, poor health, unfulfilled futures, and repeated cycles of poverty. In developing nations, energy poverty specifically contributes to more deaths of children each year than AIDS and malaria combined. There are devices, such as solar lights, which can be used to combat energy poverty, especially in areas that lack modern grid electrical supply for typical lighting devices. However, it remains a challenge to increase accessibility to these solar lights for those in need.

Many people who have not experienced energy poverty are not aware of the issue, or if they are aware, they do not know what they can do to try to solve it. Programs for building solar-powered devices exist that allow people to build a solar light device from a kit and donate these devices to communities in need. These kits allow people to get involved with a meaningful cause, putting an end to energy poverty, and the kits create excitement and passion around this cause. In turn, many of the people who contribute to building these kits continue to support the cause by donating additional time and resources, educating those around them, etc. to help these communities in need. People even donate funds to the cause to make these kits available for others to build and donate the solar lights.

Energy poverty is not completely solved by these solar light kits. There is always opportunity for more people to help with building solar lights, but it can be challenging to make the kits available in particular geographical regions or settings. In another instance, a person may be interested in supporting the cause by building a solar light, but may not be able to, for example, due to dexterity or other physical impairments. Accordingly, it would be useful to have a virtual experience for virtually building solar-powered devices. This virtual experience could spread awareness of energy poverty, generate user excitement and passion for the cause, and increase accessibility to getting involved with putting an end to energy poverty.

### SUMMARY

Described herein are systems, methods, computer-readable storage media, platforms, and graphical user interfaces for building virtual products that correspond to actual products that can be built. The computerized system can display parts of a virtual product and one or more tools to assemble the virtual product on a canvas, each of the parts and tools corresponding to those of an actual product that can be built. The computerized system can detect user inputs for building the virtual product. User inputs can include positional user inputs for positioning a part of the product relative to another part of the product. User inputs can also include fastening user inputs for attaching parts to one another. For example, the virtual product can be a solar light device that corresponds to actual solar light devices that are built from kits and donated to developing nations living in energy poverty. By creating a virtual experience to build energy resources such as solar light devices, awareness of energy poverty and overall user excitement and passion for the cause of ending energy poverty is greatly increased. Also, the opportunity to contribute to the cause by virtually building a product can increase accessibility of the cause to those who are otherwise unable to physically build a solar light but want to participate, nonetheless.

In some examples, once the virtual product is generated, the systems described herein can cause the actual product to be built. For example, an actual solar light device may be built and donated to communities in need, in turn increasing the overall number of energy resources in the hands of children and families in need.

In some examples, a computer-implemented method for generating a virtual product corresponding to an actual product is provided, the method comprising: graphically displaying a canvas comprising a plurality of parts of the virtual product and one or more tools to build the virtual product, the plurality of parts comprising a housing, a printed circuit board (PCB), a power source, and a plurality of fasteners, wherein each of the plurality of parts and the one or more tools corresponds to actual parts and tools used to build the actual product; detecting one or more positional user inputs for positioning one or more parts of the plurality of parts on the canvas in relation to one or more other parts of the plurality of parts, wherein the one or more positional user inputs comprises positioning the PCB and the power source within the housing; detecting one or more fastening user inputs for attaching the one or more parts to the one or more other parts, wherein the one or more fastening user inputs comprises using the one or more tools and one or more fasteners of the plurality of fasteners to attach the PCB and the power source to the housing; and displaying a generated virtual product on the canvas, wherein the generated virtual product corresponds to the actual product.

In some examples, detecting the one or more positional user inputs comprises determining whether the one or more parts is positioned correctly in relation to the one or more other parts. In some examples, based on a determination that the one or more parts is not positioned correctly in relation to the one or more other parts, the method comprises rejecting attachment of the one or more parts to the one or more other parts. In some examples, rejecting the attachment of the one or more parts to the one or more other parts comprises generating and displaying an indication on the canvas that a position of the one or more parts and/or the one or more other parts is incorrect. In some examples, rejecting the attachment of the one or more parts to the one or more other parts comprises generating and displaying an indication on the canvas including a hint for correctly positioning the one or more parts in relation to the one or more other parts. In some examples, based on a determination that the one or more parts is positioned correctly in relation to the one or more other parts, the method comprises generating and displaying an indication on the canvas that the one or more parts and one or more other parts are correctly attached. In some examples, the method comprises generating and transmitting an indication that the virtual product is generated. In some examples, based on the indication, the method includes causing the actual product to be built. In some examples, the one or more positional user inputs simulate positioning actual parts of the actual product. In some examples, the one or more positional user inputs comprises one or more drag-and-drop inputs on the canvas using a user input device. In some examples, the one or more fastening user inputs simulate fastening actual parts of the actual product with one or more actual fasteners and one or more actual tools. In some examples, the one or more fastening user inputs comprises one or more right-clicking inputs on the canvas using a user input device. In some examples, the plurality of parts comprises one or more wires, and wherein the method comprises detecting one or more connection user inputs for connecting the one or more wires to the PCB and to the power source. In some examples, the one or more connection user inputs simulate connecting one or more actual wires to an actual PCB and to an actual power source. In some examples, the one or more connection user inputs comprises one or more double-clicking inputs on the canvas using a user input device. In some examples, the method comprises displaying a virtual instruction manual for guiding generation of the virtual product on the canvas, and wherein the method comprises detecting one or more user inputs for navigating of the virtual instruction manual. In some examples, the one or more tools are a cursor on a graphical user interface (GUI) comprising the canvas. In some examples, the power source comprises at least one of a solar panel and a rechargeable battery.

In some examples, a system for generating a virtual product corresponding to an actual product is provided, the system comprising: a display; and one or more processors configured to cause the system to: graphically display, on the display, a canvas comprising a plurality of parts of the virtual product and one or more tools to build the virtual product, the plurality of parts comprising a housing, a printed circuit board (PCB), a power source, and a plurality of fasteners, wherein each of the plurality of parts and the one or more tools corresponds to actual parts and tools used to build the actual product; detect one or more positional user inputs for positioning one or more parts of the plurality of parts on the canvas in relation to one or more other parts of the plurality of parts, wherein the one or more positional user inputs comprises positioning the PCB and the power source within the housing; detect one or more fastening user inputs for attaching the one or more parts to the one or more other parts, wherein the one or more fastening user inputs comprises using the one or more tools and one or more fasteners of the plurality of fasteners to attach the PCB and the power source to the housing; and display, on the display, a generated virtual product on the canvas, wherein the generated virtual product corresponds to the actual product.

In some examples, detecting the one or more positional user inputs comprises determining whether the one or more parts is positioned correctly in relation to the one or more other parts. In some examples, based on a determination that the one or more parts is not positioned correctly in relation to the one or more other parts, the one or more processors are configured to cause the system to reject attachment of the one or more parts to the one or more other parts. In some examples, rejecting the attachment of the one or more parts to the one or more other parts comprises generating and displaying an indication on the canvas that a position of the one or more parts and/or the one or more other parts is incorrect. In some examples, rejecting the attachment of the one or more parts to the one or more other parts comprises generating and displaying an indication on the canvas including a hint for correctly positioning the one or more parts in relation to the one or more other parts. In some examples, based on a determination that the one or more parts is positioned correctly in relation to the one or more other parts, the one or more processors are configured to cause the system to generate and display an indication on the canvas that the one or more parts and one or more other parts are correctly attached. In some examples, the one or more processors are configured to cause the system to generate and transmit an indication that the virtual product is generated. In some examples, based on the indication, the system causes the actual product to be built. In some examples, the one or more positional user inputs simulate positioning actual parts of the actual product. In some examples, the one or more positional user inputs comprises one or more drag-and-drop inputs on the canvas using a user input device. In some examples, the one or more fastening user inputs simulate fastening actual parts of the actual product with one or more actual fasteners and one or more actual tools. In some examples, the one or more fastening user inputs comprises one or more right-clicking inputs on the canvas using a user input device. In some examples, the plurality of parts comprises one or more wires, and the one or more processors are configured to cause the system to detect one or more connection user inputs for connecting the one or more wires to the PCB and to the power source. In some examples, the one or more connection user inputs simulate connecting one or more actual wires to an actual PCB and to an actual power source. In some examples, the one or more connection user inputs comprises one or more double-clicking inputs on the canvas using a user input device. In some examples, the one or more processors are configured to cause the system to display a virtual instruction manual for guiding generation of the virtual product on the canvas, and to detect one or more user inputs for navigating of the virtual instruction manual. In some examples, the one or more tools are a cursor on a graphical user interface (GUI) comprising the canvas. In some examples, the power source comprises at least one of a solar panel and a rechargeable battery.

In some examples, a non-transitory computer-readable storage medium storing instructions for generating a virtual product corresponding to an actual product is provided, the instructions executable by a system, the system comprising a display and one or more processors, wherein execution of the instructions by the system causes the system to: graphically display, on the display, a canvas comprising a plurality of parts of the virtual product and one or more tools to build the virtual product, the plurality of parts comprising a housing, a printed circuit board (PCB), a power source, and a plurality of fasteners, wherein each of the plurality of parts and the one or more tools corresponds to actual parts and tools used to build the actual product; detect one or more positional user inputs for positioning one or more parts of the plurality of parts on the canvas in relation to one or more other parts of the plurality of parts, wherein the one or more positional user inputs comprises positioning the PCB and the power source within the housing; detect one or more fastening user inputs for attaching the one or more parts to the one or more other parts, wherein the one or more fastening user inputs comprises using the one or more tools and one or more fasteners of the plurality of fasteners to attach the PCB and the power source to the housing; and display, on the display, a generated virtual product on the canvas, wherein the generated virtual product corresponds to the actual product.

### BRIEF DESCRIPTION OF FIGURES

Various aspects of the disclosed systems and methods are set forth with particularity in the appended claims. A better understanding of the features and advantages of the disclosed systems and methods will be obtained by reference to the detailed description of illustrative embodiments and the accompanying drawings.

FIG. 1 illustrates a method for generating a virtual product corresponding to an actual product that can be built, in accordance with some embodiments.

FIGS. 2A-20 illustrate graphical user interfaces (GUIs) for generating an example virtual product, a solar light device; FIG. 2A and FIG. 2B illustrate a virtual solar light kit for generating the solar light device; FIG. 2C illustrates parts of the virtual solar light kit; FIG. 2D illustrates a pop-up window in the GUI prompting the user to answer a question prior to proceeding to the next step in building the virtual solar light device; FIG. 2E illustrates attaching a seal to a lens of the virtual solar light device; FIG. 2F and FIG. 2G illustrate attaching a PCB to the lens of the virtual solar light device; FIG. 2H illustrates connecting wires to the PCB of the virtual solar light device; FIG. 2I illustrates connecting a button to the PCB of the virtual solar light device; FIG. 2J and FIG. 2K illustrate attaching a housing to the lens and the PCB of the virtual solar light device; FIG. 2L illustrates attaching a solar panel to the housing of the virtual solar light device; FIG. 2M illustrates attaching a bumper to the housing of the virtual solar light device; FIG. 2N illustrates attaching a stand to the housing of the virtual solar light device; and FIG. 2O illustrates a virtual letter template for generating a message to be sent with an actual solar light device to be built, in accordance with some embodiments.

FIGS. 3A-3C illustrate graphical user interfaces (GUIs) for generating another example virtual product, a solar light device that includes USB ports; FIG. 3A illustrates connecting parts of the virtual solar light device; FIG. 3B illustrates fastening parts of the virtual solar light device; and FIG. 3C illustrates a coding challenge for enabling functionality of the virtual solar light device, in accordance with some embodiments.

FIGS. 4A-4I illustrate graphical user interfaces (GUIs) for generating another example virtual product, a solar light device converted from kerosene lantern; FIG. 4A illustrates a virtual kerosene lantern to be converted to the virtual solar light device; FIG. 4B illustrates parts of the virtual lantern; FIG. 4C and FIG. 4D illustrate cutting the base of a housing of the virtual solar light device; FIG. 4E and FIG. 4F illustrate assembling a light unit of the virtual solar light device; FIG. 4G illustrates positioning the light unit in the housing of the virtual solar light device; FIG. 4H illustrates fastening the light unit to the housing of the virtual solar light device; and FIG. 4I illustrates reassembling the lantern to generate the converted virtual solar light device from the virtual kerosene lantern, in accordance with some embodiments.

FIG. 5 illustrates a computing device, in accordance with some embodiments.

### DETAILED DESCRIPTION

Provided herein are systems, methods, computer-readable storage media, graphical user interfaces (GUIs), and platforms for generating virtual products that correspond to actual products that can be built. The computerized systems described herein can detect user inputs, such as positional user inputs for positioning parts of the virtual product relative to one another and fastening user inputs for attaching the parts of the virtual product to one another with one or more virtual tools. The parts of the virtual product and the tools used to virtually build the virtual product can correspond to actual parts and tools of the actual product that can be built. For example, the parts of the virtual product can include a housing, a printed circuit board (PCB), a power source, and a set of fasteners. The positional user inputs can include positioning the PCB and power source relative to the housing. The fastening user inputs can include fastening the PCB and the power source to the housing. Based on the detected user inputs, a virtual product can be generated that corresponds to an actual product that can be built. In some examples, once the virtual product is generated, the computerized system can cause the actual product corresponding to the virtual product to be built.

The following disclosure describes an exemplary method for generating a virtual product corresponding to an actual product that can be built. Following the exemplary method, example graphical user interfaces (GUIs) for assembling example virtual products-three different solar light devices—are described. Finally, an example computing device for executing the exemplary methods provided herein is described.

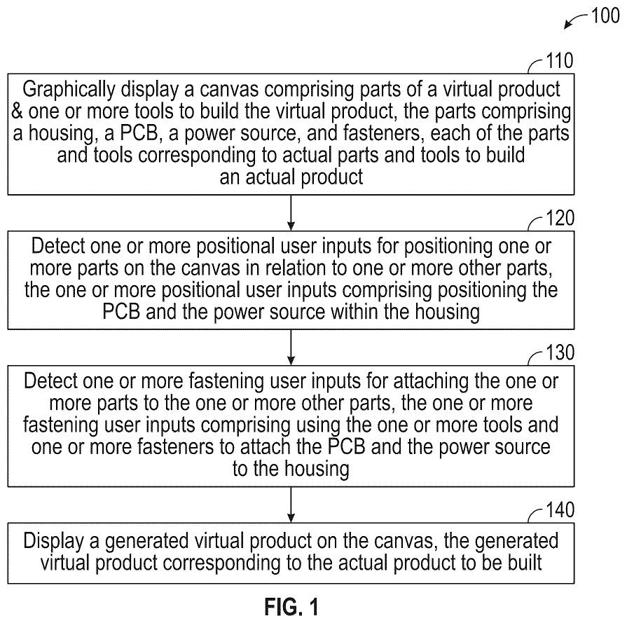

An exemplary method for generating a virtual product corresponding to an actual product that can be built is described herein with respect to method 100 illustrated in FIG. 1. At block 110 of method 100, a computerized system can graphically display (i.e., on a graphical user interface, or GUI) a canvas that includes parts of a virtual product and one or more tools to build the virtual product. The parts can include, for example, a housing, a printed circuit board (PCB), a power source, and fasteners. Each of the parts and tools correspond to actual parts and tools to build an actual product. The parts and tools displayed on the GUI can be selectable and movable on the canvas to build the virtual product. A user input device such as a touch screen, touch pad, and/or computer mouse can be used to select and move parts of the virtual product on the canvas.

In some examples, the computerized system may display a virtual instruction manual on the canvas adjacent to the parts of the virtual product. The virtual instruction manual can illustrate the steps for building the virtual product to guide the user through generation of the virtual product on the canvas. The computerized system may detect one or more user inputs for navigating the virtual instruction manual. User inputs related to the virtual instruction manual may include single-clicking (or tapping) on or scrolling the wheel of the computer mouse proximate to the virtual instruction manual to flip through pages of the manual.

At block 120 of method 100, the computerized system can detect one or more positional user inputs for positioning one or more parts on the canvas in relation to one or more other parts. The positional user input(s) can include selecting a part on the canvas, dragging the selected part to a desired region on the canvas, and deselecting (or dropping) the part in the desired region on the canvas (otherwise referred to herein as a drag-and-drop input).

In some examples, the one or more positional user inputs can include positioning the PCB and/or the power source of the virtual product within the housing. The user may select, drag, and drop the PCB to a position within the housing (or vice versa—the housing may be moved to position the PCB within the housing). A similar positional user input can be detected for the power source. The user may select, drag, and drop the power source to a position within the housing (or vice versa—the housing may be moved to position the power source within the housing).

The positional user inputs on the GUI can simulate positioning actual parts of the actual product that corresponds to the virtual product and can be built. For example, positioning the PCB and the power source within the housing on the canvas of the GUI can mimic positioning an actual PCB and an actual power source within an actual housing. In other words, the virtual parts may be sized relative to one another and may fit within one another in a manner that resembles how actual parts would be sized and fit together. This experience can generate excitement for the user because it can enable users who may be otherwise incapable of physically positioning actual parts (e.g., due to age, physical impairments, dexterity, geographic location, etc.) to experience building the product.

In some examples, detecting positional user inputs can include determining whether parts are positioned correctly relative to one another. For example, a user may select a given part and position the selected part relative to another part. Based on the position of the part(s), the computerized system may generate an indication that informs whether the part is correctly positioned on the canvas. The indication can include a visual and/or auditory indication. For example, the indication can include an audio alert, an audio message, a visual message, a visual symbol, or another visual indication that catches the user's attention. The indication may be displayed for a predetermined amount of time. If the selected part is not positioned correctly, the indication may be displayed until the position of the part is correct. Additionally or alternatively, if the part is not positioned correctly, the indication may include a hint displayed on the canvas for correctly positioning part(s).

In examples in which the part is not positioned correctly, the computerized system may prohibit the user from continuing to the next step in generating the virtual product until the part is positioned correctly. The next step in generating the virtual product could be attaching the parts positioned relative to one another, so in this situation, the computerized system may reject the attachment of the parts. In examples in which the part is positioned correctly, the computerized system may enable the user to proceed to the next step in generating the virtual product.

In some examples, a cursor can be displayed on the GUI that corresponds with the detected user input. For example, when the cursor is hovered above a part of the virtual product that is to be selected and moved in a given step of the process, the cursor may change from a standard arrow to an animated hand that is open. When the user selects the part, the cursor may change to an animated hand that grips the selected part. When the user deselects the part, the cursor may change back to an animated hand that is open (or a standard arrow).

At block 130 of method 100, the computerized system can detect one or more fastening user inputs for attaching parts of the virtual product. If the user input device is a handheld device such as a computer mouse, the fastening user input may include single-clicking, double-clicking, scrolling the wheel of the computer mouse, right-clicking, left-clicking, clicking and holding (for a predetermined amount of time), clicking and dragging, or a combination thereof. If the user input device is a touch screen or touch pad, the fastening user input can include a single tap, a double tap, tapping with more than one finger, tapping and holding, tapping and dragging, or a combination thereof.

The fastening user inputs can use the one or more tools and one or more fasteners to attach the parts. For example, the user may position a fastener relative to the parts to be attached in accordance with the positional user input described above, and then may select a tool to fasten the fastener. When selected, the fastener can be the cursor on the GUI. Using the tool, the user can fasten the fastener to the parts to attach the parts in accordance with any one or more of the above-described fastening user inputs. For example, the computerized system may detect right-clicking (or tapping) to fasten the fastener. In this manner, the tool(s) and fasteners can be used to attach the PCB and/or the power source that have been positioned within the housing to the housing.

The fastening user inputs on the GUI can simulate fastening actual parts of the actual product that can be built with actual fasteners. For example, fastening the PCB to the housing on the canvas of the GUI can mimic fastening an actual PCB to an actual housing with actual fasteners and tools by rotating the virtual tool(s) and fasteners to thread the fasteners into the virtual PCB and housing. This experience can be meaningful for the user because it can enable users who may be otherwise incapable of physically attaching actual parts to experience building the product. For example, attaching actual parts with small fasteners and potentially complicated tools can be challenging for some people (e.g., due to age, physical impairments, dexterity, etc.).

In some examples, the parts of the virtual product can include one or more wires for electrically connecting parts of the virtual product. In these examples, method 100 can include detecting one or more connection user inputs for connecting the wire(s). The one or more wires can be used to connect the PCB and the power source of the virtual product. The connecting user input may utilize the user input device (e.g., computer mouse, touch screen, touch pad, etc.) in a manner described above with respect to the fastening user inputs. For example, the user may double-click (or tap), right-click, etc. to connect the wire(s) to PCB and the power source.

The connection user inputs can simulate connecting one or more actual wires to actual parts of the actual product. For example, the wire(s) may extend on the canvas of the GUI to illustrate length in the wire(s) when electrically connecting the PCB and the power source. This experience can generate excitement in the user because it can simplify an experience that otherwise could be dangerous in real life and allow the user to experience it risk-free virtually. For example, connecting wires can require solder or other types of welds that could require expertise or training to execute in real life. By mimicking this virtually, users who may otherwise be unable to complete this action can still experience it, and without the danger or risk.

At block 140 of method 100, the computerized system can display a generated virtual product on the canvas that corresponds to the actual product that can be built. The user may interact with the virtual product in a manner that simulates interaction with the actual product corresponding to the virtual product. For example, the user may turn the virtual product on and/or off, move and/or rotate the product on the canvas, etc. Seeing and having the opportunity to interact with a virtual product that the user built can create excitement for and a sense of ownership of the product. Users may want to participate in the build again and continue virtually generating products.

In some examples, once the virtual product is generated, the computerized system may generate and transmit an indication that the virtual product is generated. For example, the virtual product may be generated by an end-user using a front-end GUI of the computerized system, and the computerized system may transmit an indication to a back-end system that indicates that the virtual product has been generated. The back-end system can automatically cause an actual product to be built (e.g., by an automated or semi-automated manufacturing process). In some examples, the back-end system may be accessible by an administrative user that receives the indication of the generated virtual product and in turn causes an actual product to be built (e.g., automatically by a manufacturing process or by hand). In this manner, for each virtual product that is generated, an actual product corresponding to the virtual product is built. The actual product can be provided to an actual person for use. Example products can include energy resources (e.g., solar lights) and other necessary devices, which can be donated to communities in need.

In some examples, a user may be able to build virtual products using the virtual building platforms described herein with a donation. The donation may fund building of the actual product that corresponds to the virtually built product. The cost of some actual products that may be virtually built using the virtual building platforms described herein may exceed the monetary amount of donation received to build the corresponding virtual product. Nonetheless, a user may be able to build the virtual product using the virtual building platform, and the donation may be used to fund a portion of the actual product to be built. Thus, a 1:1 ratio of virtual product built to actual product to be built is not required. Rather, for every 1, 2, 5, 10, etc. virtual products built, 1 actual product (i.e., 2:1, 5:1, 10:1, etc.) may be built. The number of actual products built from one donation and/or building one virtual product may vary based on the cost to build the actual product.

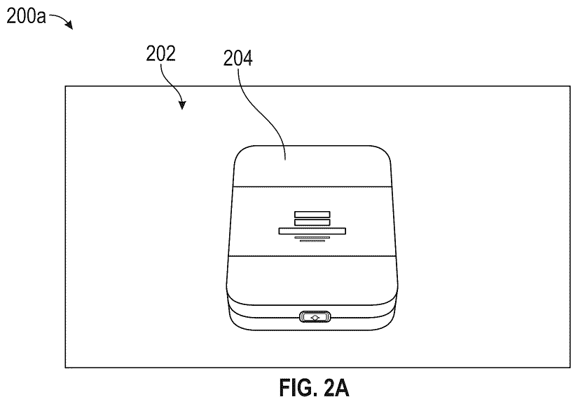

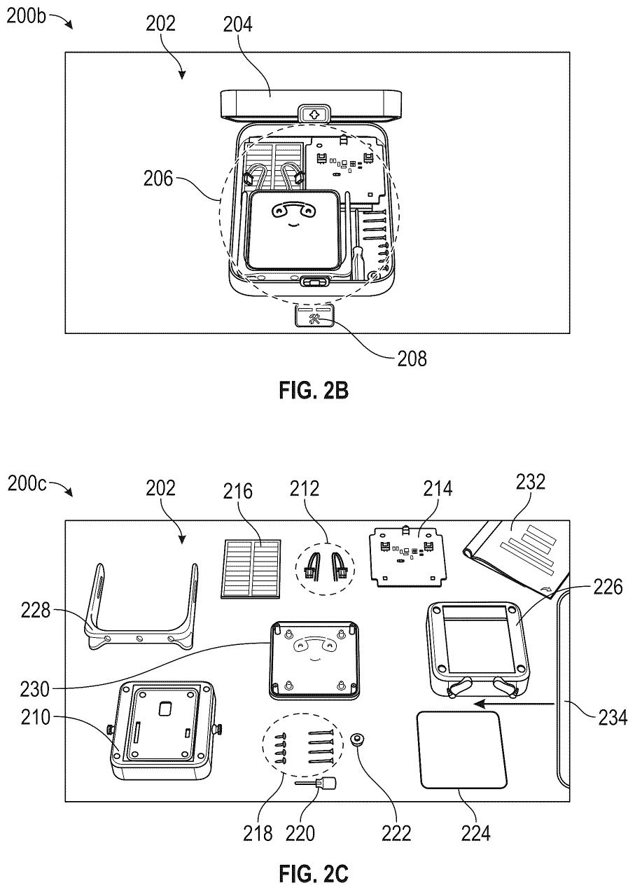

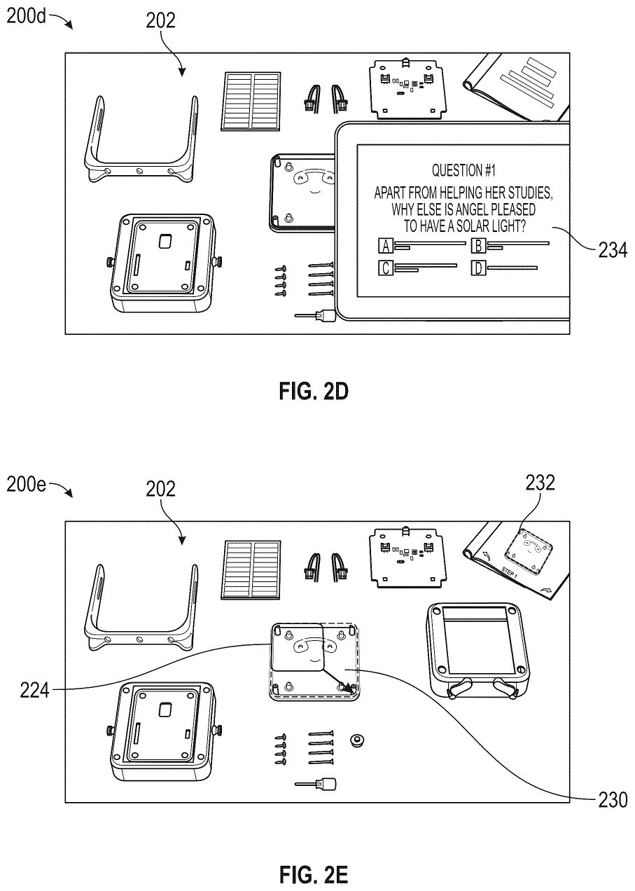

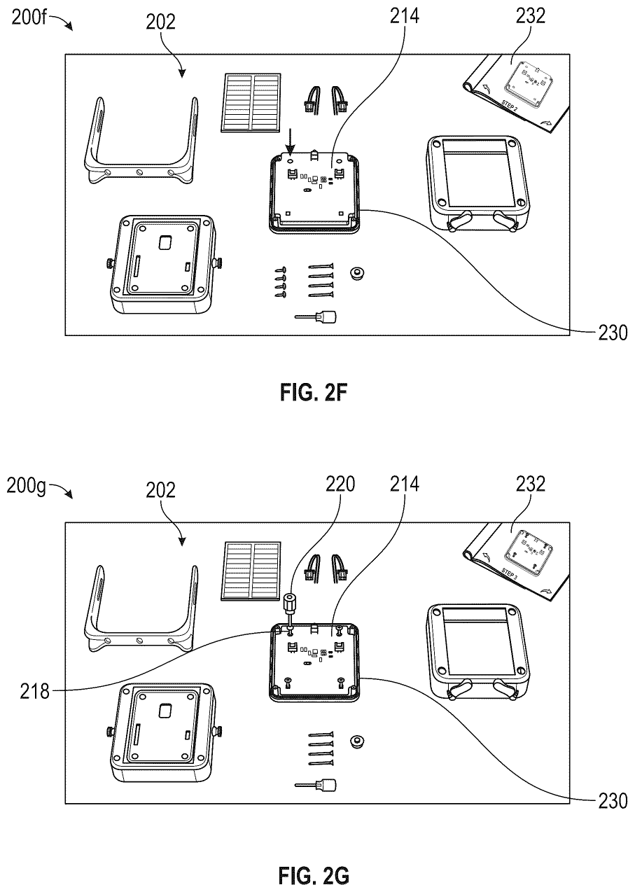

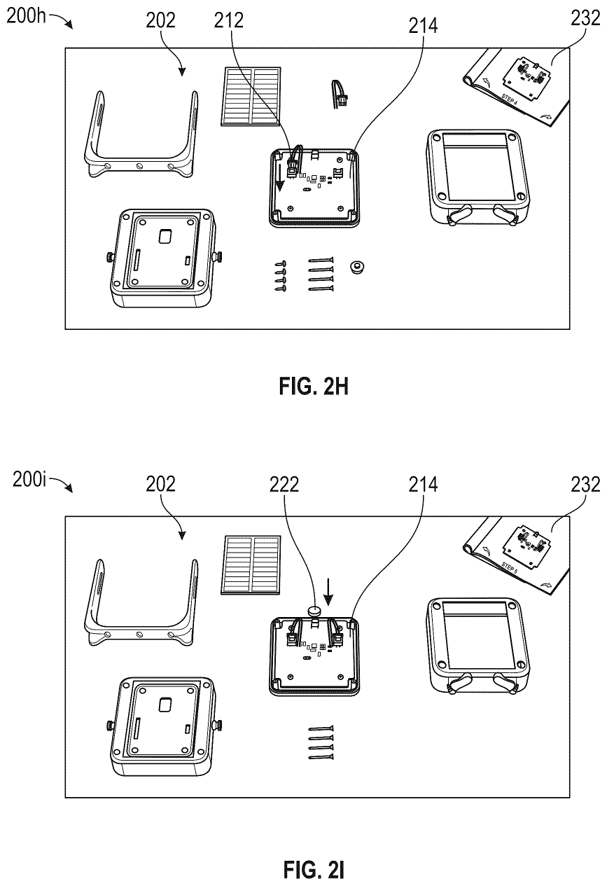

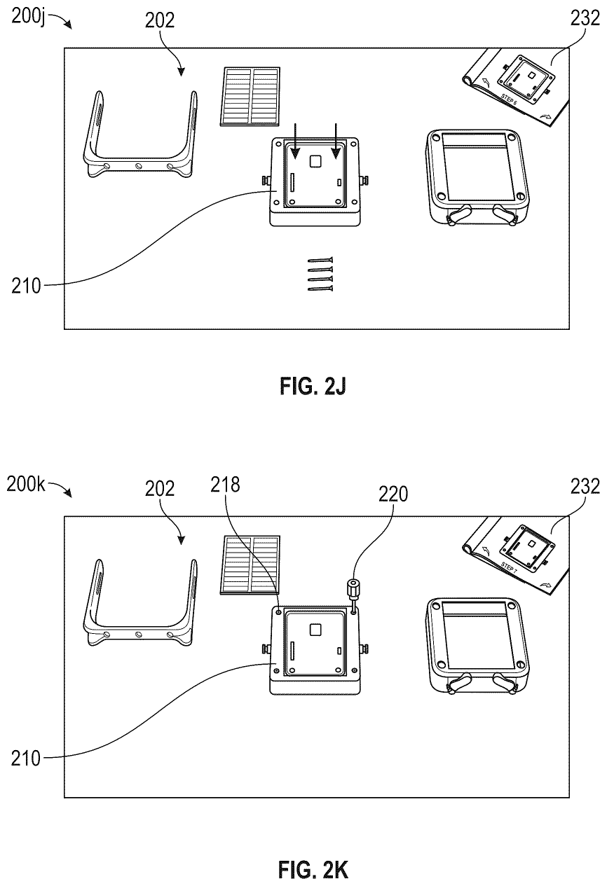

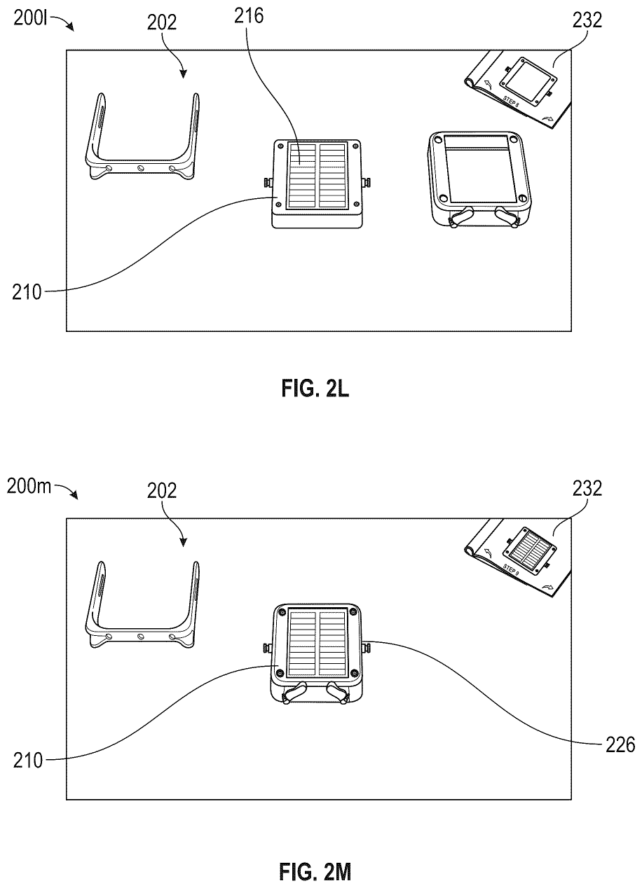

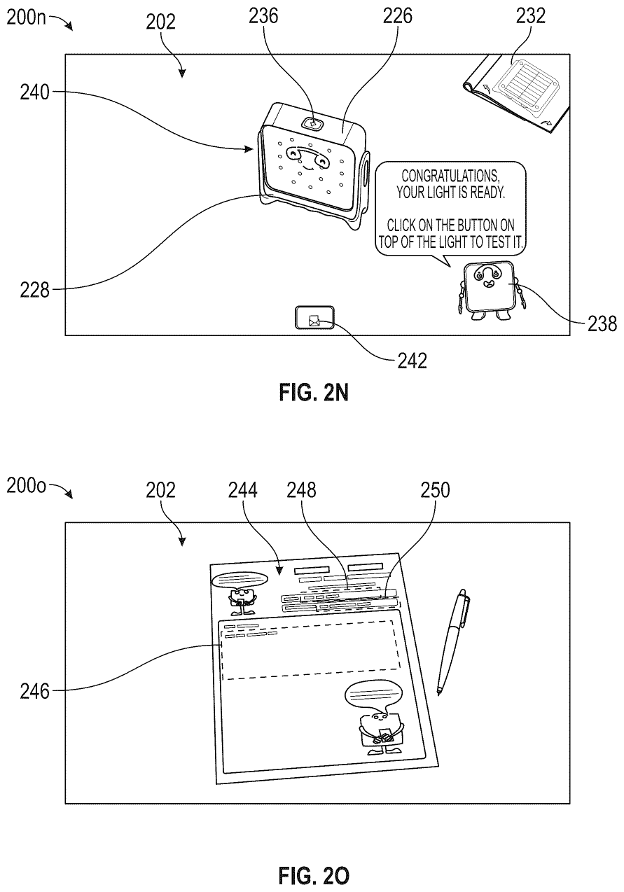

As noted above, example virtual products that can be generated using the methods, systems, and platforms provided herein can include energy resources, such as solar light devices. FIGS. 2A-20, FIGS. 3A-3C, and FIGS. 4A-4I illustrate example GUIs of a virtual building platform for generating virtual solar light devices in accordance with the methods described herein. Each of the virtual solar light devices correspond to actual solar light devices that can be built. Creating a virtual solar light device that corresponds to an actual solar light device that can be donated to someone in need can generate excitement around the cause of the solar light device, reducing energy poverty, in turn increasing the impact of the cause. In some examples, upon completion of generating the virtual solar light device, an actual solar light device will be built.

GUI 200a illustrated in FIG. 2A depicts a canvas 202 for building a virtual solar light device. The solar light device may be provided in a virtual kit that includes parts for building the virtual product. The parts of the virtual kit can be stored in a package 204. The user of GUI 200a may engage with the package 204, for example, by clicking (or tapping) the package 204 to cause the package 204 to open.

GUI 200b illustrated in FIG. 2B depicts the package 204 on the canvas 202 after it is opened. The parts 206 of the virtual product are shown within the package 204. As shown in FIG. 2B, once the package 204 is opened, the user of GUI 200b may engage with a button 208 or other graphical user object on the canvas 202, a key on a user input device (e.g., a keyboard) that causes the parts 206 of the virtual solar light device to be removed from the package 204 so that the user can begin building the virtual solar light device.

GUI 200c illustrated in FIG. 2C depicts the parts of the virtual solar light device laid out on the canvas 202. The parts can include, without limitation, a housing 210, a set of wires 212, a printed circuit board (PCB) 214, a solar panel 216, a set of fasteners 218, a tool 220, a button 222, a seal 224, a bumper 226, a handle 228, and a lens 230. GUI 200c also includes a virtual instruction manual 232 that the user can interact with to guide them through generating the solar light device. It is noted that in each of the GUIs illustrated in FIGS. 2E-2N, the virtual instruction manual 232 depicts the building step that corresponds to the building step being executed using the given GUI (e.g., the building step illustrated in the virtual instruction manual 232 in FIG. 2E corresponds to the building step depicted in GUI 200e in FIG. 2E). Using the virtual building platform described herein, the user can freely engage with the virtual instruction manual 232 in any manner, not necessarily corresponding to the different GUIs depicted.

Building the solar light device using the virtual building program illustrated in FIGS. 2A-20 may be completed in conjunction with watching a series of videos and answering multiple-choice questions based on the videos. For example, before each step for building the virtual solar light device, the user may be required to watch a video and answer a multiple-choice question related to the video. In combination with the building experience, the videos and questions enable the user to learn more about the purpose of the solar light device being built and can increase excitement and passion for the cause of reducing energy poverty. In the GUI 200c illustrated in FIG. 2C, a window 234 that provides the video and question is shown as partially hidden in canvas 202. The user of the GUI 200c may engage with the window 234 by clicking on the window 234 to cause the window to move into view, as illustrated by the horizontal arrow extending from the window 234 in FIG. 2C.

GUI 200d illustrated in FIG. 2D depicts the window 234 in full view with a question displayed on the window 234 for the user to answer. When the window 234 initially comes into view on the canvas 202, a video may automatically begin playing. In some examples, the user may cause the video to start playing, e.g., by selecting a “play” icon on the GUI 200d. The video may be paused, rewound, restarted, etc. by the user. After the video is complete, one or more questions related to the video may be displayed on the window 234. The user may engage with the window 234 by selecting (e.g., clicking or tapping) an answer to the question(s). The videos and associated questions can be related to the background and impact of the solar light device that is being virtually built. In some examples, in addition to or instead of watching videos, the user may be required to read passages, listen to audio recordings, reflect on their own experiences, etc. In addition to or instead of multiple-choice questions, the user may be required to answer a fill-in-the-blank question, short-answer question, true/false question, etc.

Once the correct answer to the question is received, the window 234 may automatically recede to the side of the canvas 202 (as illustrated in and previously described with respect to FIG. 2C). The user may be allowed to proceed with the next step of the virtual building process. In the following steps illustrated and described with respect to FIGS. 2E-2N, the window 234 for displaying the video and associated question(s) is not shown, however, it is to be understood that the window 234 may be displayed in a similar manner as described above with respect to FIGS. 2C-2D between any of the steps of the virtual building process.

As described above, generating a virtual product, such as the virtual solar light device described herein with respect to FIGS. 2A-20, can include detecting one or more positional user inputs for positioning parts of the virtual product. In the GUI 200e illustrated in FIG. 2E, the detected positional user input can include detecting the user positioning the seal 224 relative to the lens 230 to attach the seal 224 to the perimeter of the lens 230. An actual seal may be elastic, so the seal 224 may stretch (as illustrated) to mimic this elasticity. The user may select the seal 224 on the canvas 202, move the seal 224 to a corner of the lens 230, and drag the seal 224 to the corner opposite and diagonal from the original corner of the lens 230 to fit the seal 224 onto the perimeter of the lens 230. As noted above, this type of positioning interaction with the user interface can generate excitement for the user because it can enable the user to complete a virtual action they may have been otherwise unable or unfamiliar with how to complete with actual tangible parts.

The GUI 200f illustrated in FIG. 2F depicts another positional user input that may be detected in generating the virtual solar light device. In GUI 200f, the detected positional user input can include detecting the user positioning the PCB 214 relative to the lens 230 to facilitate subsequent attachment of the PCB 214 and the lens 230. The user may select, drag, and drop the PCB 214 so that it is positioned on the lens 230. In some examples, once the PCB 214 is correctly positioned, the user may click or tap (e.g., double-click, right-click, etc.) the PCB 214 to lock the PCB 214 into place on the canvas 202.

As described above, generating the virtual product can include detecting one or more fastening user inputs for attaching parts of the virtual product. In the GUI 200g illustrated in FIG. 2G, the detected fastening user input can include detecting the user fastening a set of fasteners 218 to the PCB 214 to attach the PCB 214 to the lens 230. Prior to detecting the fastening user input, the computerized system may detect positional user inputs for positioning the fasteners 218 relative to the corresponding holes of the PCB 214. These positional user inputs may include drag-and-drop inputs. Once the fasteners 218 are correctly positioned, the user may select the tool 220 (e.g., a virtual screwdriver) for fastening the fasteners 218 to the PCB 214. When the tool 220 is selected, the cursor on the GUI 200g may be the tool 220. Using the tool 220, the user may click or tap (e.g., right-click, double-click, etc.) each of the fasteners 218 to cause the fasteners 218 to be fastened into the holes of the PCB 214. As noted above, this type of fastening interaction with the user interface can be exciting for the user because it can enable the user to complete a virtual action they may have been otherwise unable to complete with actual tangible parts.

As mentioned above, generating the virtual product can include detecting one or more connection user inputs for connecting wires to parts of the virtual product. In the GUI 200h illustrated in FIG. 2H, the detected connection user input can include detecting the user connecting the wires 212 to the sockets of the PCB 214. Prior to detecting the connection user input, the computerized system may detect positional user inputs for positioning the wires 212 relative to the corresponding sockets of the PCB 214. These positional user inputs can include drag-and-drop inputs. Once the wires 212 are correctly positioned, the user may double-click (or tap), right-click, etc. the wires 212 to connect the wires to the sockets of the PCB 214. As noted above, this type of connection using the user interface can generate excitement for the user because it can enable the user to complete a virtual action they may have been otherwise unable to complete with actual tangible parts. For example, connecting actual wires to an actual PCB could involve the use of solder or welding, but the virtual interactions described herein may simulate that without the risk or know-how necessary to complete the interaction.

GUI 200i illustrated in FIG. 2I depicts another positioning user input in which the computerized system detects the user selecting the button 222 on the canvas 202 and positioning the button 222 relative to a corresponding switch of PCB 214. Once the button 222 is correctly positioned, the user can lock the button 222 in place on the PCB 214, e.g., by right-clicking or double-clicking the button 222.

GUI 200j illustrated in FIG. 2J depicts another positioning user input in which the computerized system detects the user selecting the housing 210 on the canvas 202 and positioning the housing 210 relative to the already assembled parts of the virtual solar light device (e.g., the lens 230, the PCB 214, etc.) to enclose the aforementioned parts of the virtual solar light device in the housing 210.

The housing 210 may include a power source, such as a rechargeable battery, thereon. In some examples, positioning the housing 210 relative to the PCB 214 may simulate electrically connecting the PCB 214 and the power source within the housing 210. In some examples, the computerized system may instead detect a connecting user input for connecting the PCB 214 and the power source of the housing 210 via wires 212.

GUI 200k illustrated in FIG. 2K depicts another fastening user input (following a positioning user input) in which the computerized system first detects the user selecting fasteners 218 on the canvas 202 and positioning the fasteners 218 relative to the corresponding holes in the housing 210. Following correct positioning of the fasteners 218, the computerized system detects the user selecting the tool 220 and using the tool 220 to fasten the fasteners 218 to the housing 210 (e.g., in a similar manner as described above with respect to fastening the PCB 214 to the lens 230 in GUI 200g illustrated in FIG. 2G). Once fastened, the electronic components of the virtual solar light device can be enclosed in the housing 210.

GUI 200l illustrated in FIG. 2L depicts another positioning user input in which the computerized system detects the user selecting the solar panel 216 on the canvas 202 and positioning the solar panel 216 relative to the corresponding receiving portion of the housing 210. In some examples, the user may lock the solar panel 216 to the housing 210 by right-clicking or double-clicking the solar panel 216. In some examples, locking the solar panel 216 to the housing 210 may simulate electrically connecting the PCB 214 within the housing 210 to the solar panel 216. In some examples, the computerized system may instead detect a connecting user input for connecting the PCB 214 and the solar panel 216 via wires 212.

GUI 200m illustrated in FIG. 2M depicts another positioning user input in which the computerized system detects the user selecting the bumper 226 on the canvas 202 and positioning the bumper 226 relative to the housing 210. In some examples, the user may attach the bumper 226 to the housing 210 by right-clicking or double-clicking the bumper 226.

GUI 200n illustrated in FIG. 2N depicts another positioning user input in which the computerized system detects the user selecting the handle 228 on the canvas 202 and positioning the handle 228 relative to the bumper 226. In some examples, the user may attach the handle 228 to the bumper 226 by right-clicking or double-clicking the handle 228.

FIG. 2N illustrates a complete virtual solar light device 240. When the virtual solar light device 240 is fully generated, the user may interact with the virtual solar light device 240, e.g., to test the functionality of the device, move the device around on the canvas 202, etc. For example, the user may engage with the button 236 on the virtual solar light device 240 to turn the light on and off. Interacting with the generated solar light device can create a sense of pride for the user because they completed the task of building the device. It can be exciting for the user to interact with the device and see how it actually works and looks for the children and families that the actual solar light devices are donated to. These types of interactions can create a lasting impact on the user that generates excitement and passion for the cause of reducing energy poverty in developing nations.

In some examples, in addition to or instead of the virtual instruction manual 232, the virtual building platform can include a virtual assistant 238 (illustrated in FIG. 2N) that guides the user through building the virtual product. The virtual assistant 238 may generate textual instructions that may be displayed on the GUI and/or delivered as audio via a speaker.

As noted above, generating the virtual solar light device 240 can cause an actual solar light device to be built. In some examples, the user can create a personal message to accompany the actual solar light device to be built. Having the opportunity to create a personal message that will be shared with a recipient of an actual solar light can contribute to creating a lasting impact on the user and can build the user's excitement for the cause of ending energy poverty. The GUI 200n includes a button 242 that the user may select to cause a letter template to be displayed for generating the message.

GUI 2000 illustrated in FIG. 2O depicts an example letter template 244 on the canvas 202 for generating a personal message that can accompany the actual solar light device that will be built. The letter template 244 includes several text fields, including a message field 246, name field 248, and organization field 250 that the user can select and insert text to. In examples in which the user input device is a touch screen device, selecting one or more of the text fields on the letter template 244 can cause a keyboard to be displayed on the GUI 2000. Again, in examples in which the user input device is a touch screen device, the computerized system may detect a user input on GUI 2000 that includes writing or drawing on the touch screen device.

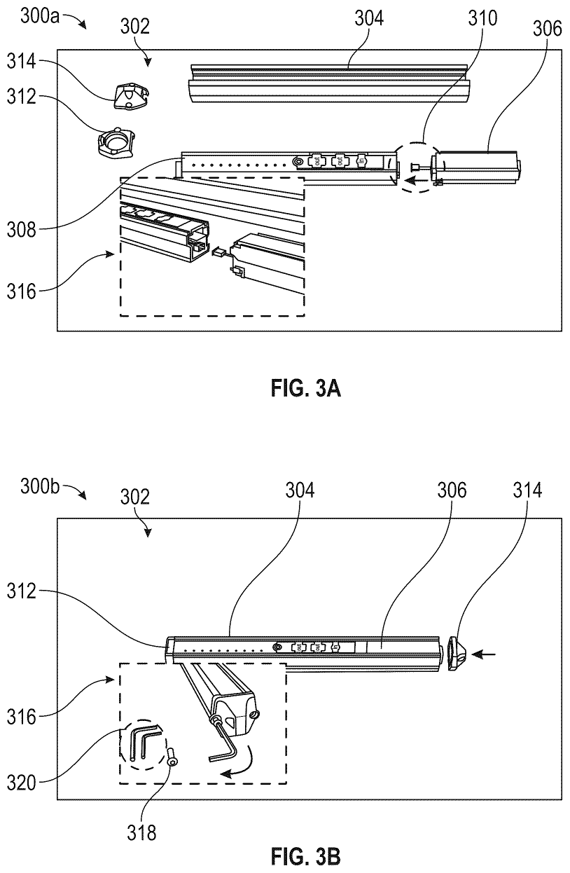

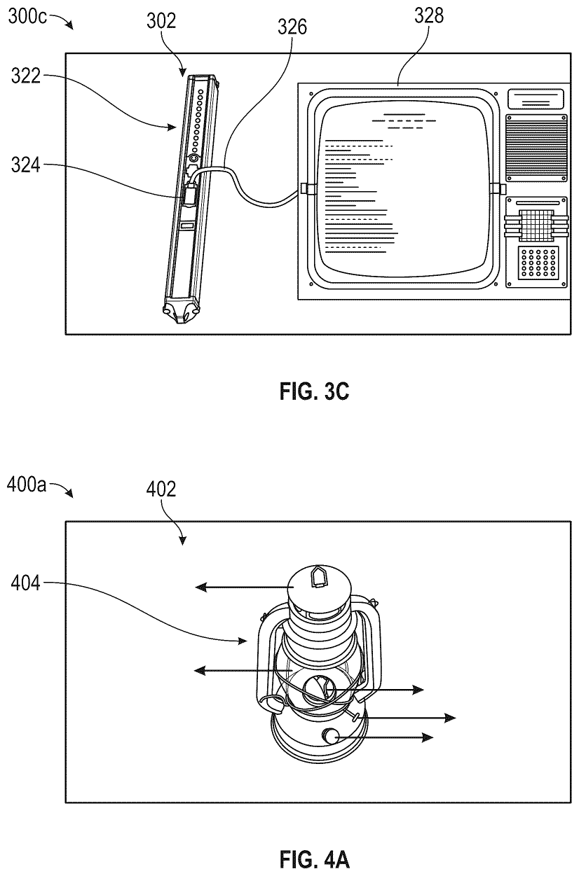

Another virtual solar light device that can be generated using the virtual building platforms described herein is illustrated in FIGS. 3A-3C. GUI 300a illustrated in FIG. 3A depicts a canvas 302 on which parts of the virtual solar light device are laid out. In GUI 300a illustrated in FIG. 3A, the parts of the virtual solar light device are partially assembled and include, without limitation, a housing 304, a power source 306, a printed circuit board (PCB) (which may be already attached to a light source), an end piece 312, and an end piece 314.

GUI 300a illustrated in FIG. 3A depicts a connection user input in which the computerized system detects the user electrically connecting the PCB 308 and the power source 306 via a wire 310. The user may first position the power source 306 relative to the PCB 308 and may connect the wire 310 extending from the power source to the PCB 308. In GUI 300a, a pop-up window 316 is illustrated to provide the user with a detailed view of the connection. The pop-up window 316 may be displayed in the GUI 300a when the user selects the power source 306 and positions it proximate to the PCB 308 to facilitate electrical connection of the parts with the wire 310.

GUI 300b illustrated in FIG. 3B depicts a fastening user input (following a positioning user input) in which the computerized system first detects the user selecting one or more fasteners 318 and positioning the fasteners 318 relative to the corresponding holes in the end piece 314. Following correct positioning of the fasteners 318, the computerized system detects the user selecting one or more of the tools 320 (e.g., one or more Allen keys) and using the tool 320 to fasten the fasteners 318 to attach the end piece 314 to the housing 304. Similar to GUI 300a, a pop-up window 316 may be displayed in GUI 300b to facilitate positioning and fastening the fastener(s) 318.

A generated virtual solar light device 322 is illustrated in GUI 300c of FIG. 3C. FIGS. 3A-3B are not intended to be representative of the complete build of the virtual solar light device 322 (and the actual solar light device corresponding to it)—they are illustrative of a portion of the building process. Virtual solar light device 322 is an example virtual product that can be generated using the virtual building platforms provided herein.

The virtual solar light device 322 may be different from that which is described above with respect to FIGS. 2A-20 in that the virtual solar light device 322, like the actual solar light device that corresponds to it, may include universal serial bus (USB) ports for connecting to another electronic device. Using the actual solar light device corresponding to virtual solar light device 322, other electronic devices that are connected to the solar light device can be powered or charged. An example of this functionality of the solar light device is depicted in GUI 300c illustrated in FIG. 3C. In GUI 300c, the virtual solar light device 322 connects to a virtual device 328 via a wire 326. The user may interact with the virtual device 328 to complete a coding challenge. As the coding challenge is completed, the light sources of the virtual solar light device 322 are activated. Once the coding challenge is completed, the virtual solar light device 322 will be fully functional. In some examples, once the coding challenge is completed, the computerized system can cause an actual solar light device that corresponds to the virtual solar light device 322 to be built. This type of experience can be exhilarating for a user because it can motivate the user to complete the coding challenge and witness their virtually built solar light device as a fully functional device. The user can feel a sense of pride from completing both the virtual build and the accompanying coding challenge.

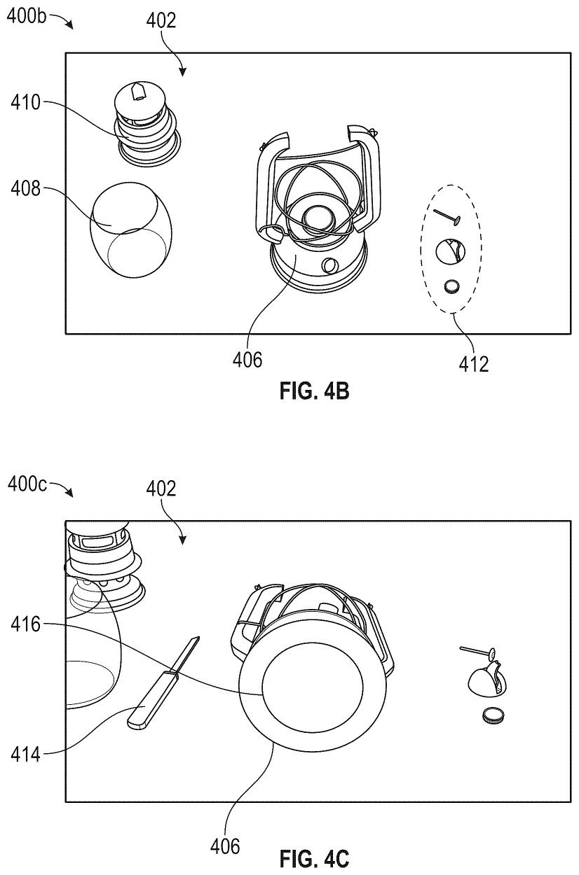

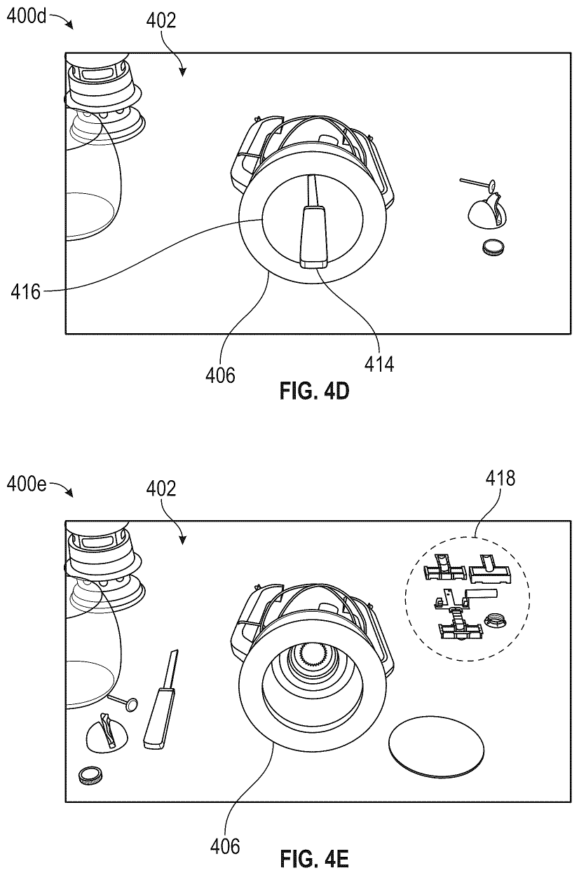

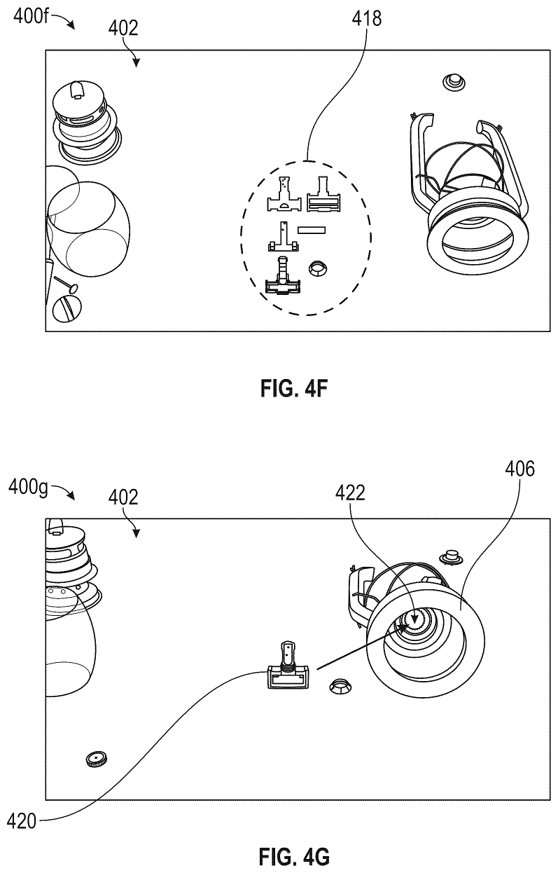

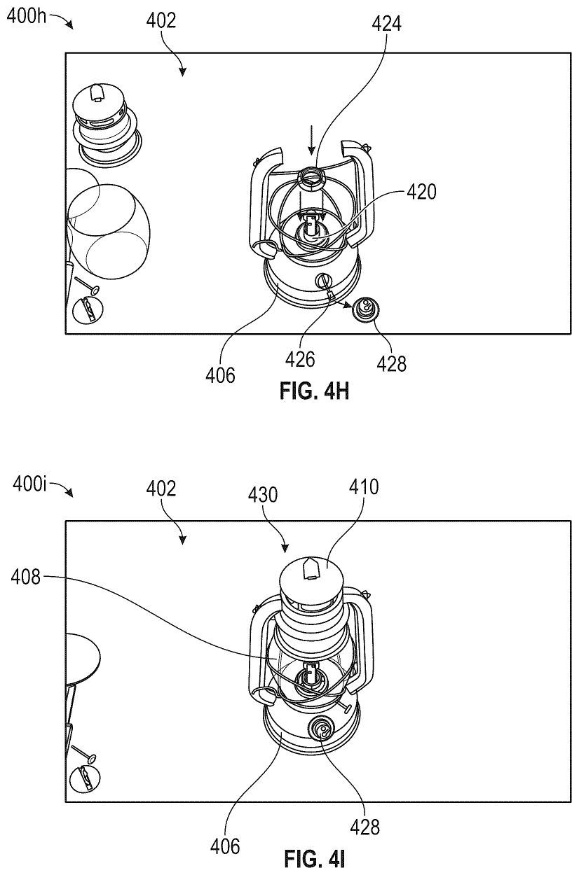

Another virtual solar light device that can be generated using the virtual building platforms described herein is illustrated in FIGS. 4A-4I. The virtual solar light device illustrated in FIGS. 4A-4I may differ from that which is described above in that the virtual solar light device is generated by converting a virtual kerosene lantern to a virtual solar light device. The actual product corresponding to the virtual solar light device generated in FIGS. 4A-4I is a solar light device that is built by converting an existing kerosene lantern to a solar light device. Building this type of solar light device can increase awareness to the user of the platform that children and families in developing nations are continuing to use dangerous and harmful energy sources today. Showing the user of the platform how these kerosene lanterns can be repurposed to clean energy (solar light) devices can be extremely impactful and can inspire the user to contribute to the cause of ending energy poverty. It can also educate users of the platform of the concept of a circular economy in which, rather than introducing a new product, an existing product is given a second life, thus reducing waste.

GUI 400a illustrated in FIG. 4A depicts a canvas 402 with a virtual kerosene lantern 404 disposed on it. The computerized system can detect positional user inputs to disassemble the parts of the virtual kerosene lantern 404. The GUI 400b illustrated in FIG. 4B depicts parts of the virtual kerosene lantern 404 laid out on the canvas 402, including a base 406, enclosure 408, cap 410, and wick components 412.

GUI 400c illustrated in FIG. 4C depicts a positional user input in which the computerized system detects the user positioning the base 406 such that the bottom face of the base 406 is visible. The user may select the tool 414 (e.g., a saw), which can cause an outline 416 to appear on the base 406 in the GUI 400c. As illustrated in GUI 400d in FIG. 4D, the computerized system can detect the user tracing the outline 416 with the tool 414 to cut the bottom face of the base 406. The base 406 with the cut-out therein is illustrated in GUI 400e of FIG. 4E.

Once the bottom face of the base 406 is cut out, the user can build the light unit of the device. The GUI 300e illustrated in FIG. 4E depicts components 418 of the light unit laid out on the canvas 402. The computerized system may detect a user input selecting the components 418 of the light unit to bring the components 418 into a closer view for building the light unit. The view is illustrated in GUI 400f of FIG. 4F. Building the light unit with the components 418 can include one or more positional user inputs, fastening user inputs, and/or connection user inputs, as described above.

GUI 400g illustrated in FIG. 4G depicts another positional user input in which the computerized system detects the user positioning the built light unit 420 into a receiving portion 422 of the base 406. When the light unit 420 is positioned correctly relative to the base 406, the light unit 420 may move (e.g., rotate) on the GUI 400g to fit into the receiving portion 422 of the base 406.

GUI 400h illustrated in FIG. 4H depicts a fastening user input in which the computerized system detects the user fastening a collar 424 to a corresponding portion of the base 406 to lock the light unit 420 into the base 406. The user may first position the collar 424 relative to the light unit 420 to enable the collar 424 to attach the light unit 420 with the base 406. In some examples, the user may double-click, right-click, etc. to cause the collar 424 to rotate in the GUI 400h and fasten onto the base 406.

GUI 400h also depicts a connection user input in which the computerized system detects the user electrically connecting a wire 426 extending from within the base 406 (from the light unit 420) to a power button 428.

GUI 400i illustrated in FIG. 4I depicts a generated virtual solar light device 430. The build of the virtual solar light device 430 can be completed using one or more positional user inputs. For example, the computerized system can detect the user positioning the power button 428 relative to a corresponding opening in the base 406. The power button 428 may be attached to the base 406 when the user right-clicks or double-clicks the power button 428 (after correctly positioning the power button 428 relative to the base 406). Another positional user input detected by the system that is depicted in GUI 400i can include the user positioning the cap 410 relative to the top of base 406. The cap 410 may be reattached to the base 406 when correctly positioned by right-clicking or double-clicking the cap 410.

When the user completes the build of the virtual solar light device 430, the computerized system can cause an actual solar light device corresponding to the virtual solar light device 430 to be built. This can include causing at least the light unit and a switch unit of solar light device to be built and provided to the end user for the end user to retrofit into their existing kerosene lantern. In some examples, the actual light unit and switch unit can be provided to a female micro-entrepreneur in a country experiencing energy poverty to provide the female micro-entrepreneur the opportunity to create a small business that retrofits kerosene lanterns for their customers and thus provides repurposed clean energy light sources for their community.

The systems, methods, platforms, and graphical user interfaces described herein for generating virtual products that correspond to actual products that can be built are not limited to solar light devices. Other devices that may be virtually generated may include but are not limited to solar grids (e.g., micro and/or mini grids), kitchen appliances (e.g., a cooler, cooktop, etc.), bikes, e-bikes, chimney, e-reader, water filters, and wheelchairs. The solar grids can be used to power buildings (e.g., schools, health care facilities, homes, etc.) of a communities experiencing energy poverty. Any of the aforementioned devices can be solar powered. One or more of the aforementioned products may be a second life product that is repurposed from an existing related product in the economy (i.e., similar to the solar light device 430 repurposed from a kerosene lantern).

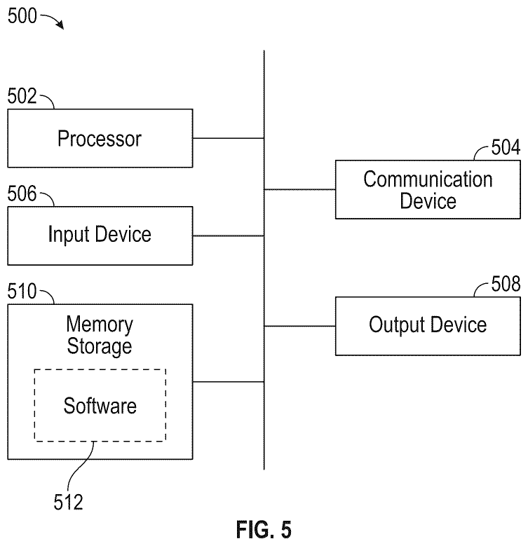

FIG. 5 depicts a computing device 500, according to one or more examples of the disclosure. In one or more examples, computing device 500 may be configured to execute the method 100 for generating a virtual product corresponding to an actual product that can be built. In one or more examples, computing device 500 may be configured to generate and display graphical user interfaces (GUIs) for generating virtual products, such as the GUIs illustrated in FIGS. 2A-20, 3A-3C, and 4A-4I for generating solar light devices.

Computing device 500 can be a host computer connected to a network. Computing device 500 can be a client computer or a server. As shown in FIG. 5, computing device 500 can be any suitable type of microprocessor-based device, such as a personal computer, workstation, server, or handheld computing device (portable electronic device) such as a phone or tablet. The computing device 500 can include, for example, one or more of processors 502, input device 506, output device 508, storage 510, and communication device 504.

Input device 506 can be any suitable device that provides an input, such as a touch screen, keyboard or keypad, mouse, or voice-recognition device. Output device 508 can be any suitable device that provides output, such as a display, touch screen, haptics device, or speaker.

Storage 510 can be any suitable device that provides storage, such as an electrical, magnetic, or optical memory, including a RAM, cache, hard drive, or removable storage disk. Communication device 504 can include any suitable device capable of transmitting and receiving signals over a network, such as a network interface chip or device. The components of the computer can be connected in any suitable manner, such as via a physical bus or wirelessly.

Software 512, which can be stored in storage 510 and executed by processor 502, can include, for example, the programming that embodies the functionality of the present disclosure (e.g., as embodied in the devices as described above).

Software 512 can also be stored and/or transported within any non-transitory computer-readable storage medium for use by or in connection with an instruction execution system, apparatus, or device, such as those described above, that can fetch instructions associated with the software from the instruction execution system, apparatus, or device and execute the instructions. In the context of this disclosure, a computer-readable storage medium can be any medium, such as storage 510, that can contain or store programming for use by or in connection with an instruction execution system, apparatus, or device.

Software 512 can also be propagated within any transport medium for use by or in connection with an instruction execution system, apparatus, or device, such as those described above, that can fetch instructions associated with the software from the instruction execution system, apparatus, or device and execute the instructions. In the context of this disclosure, a transport medium can be any medium that can communicate, propagate, or transport programming for use by or in connection with an instruction execution system, apparatus, or device. The transport readable medium can include, but is not limited to, an electronic, magnetic, optical, electromagnetic, or infrared wired or wireless propagation medium.

Computing device 500 may be connected to a network, which can be any suitable type of interconnected communication system. The network can implement any suitable communications protocol and can be secured by any suitable security protocol. The network can comprise network links of any suitable arrangement that can implement the transmission and reception of network signals, such as wireless network connections, T1 or T3 lines, cable networks, DSL, or telephone lines.

Computing device 500 can implement any operating system suitable for operating on the network. Software 512 can be written in any suitable programming language, such as C, C++, Java, or Python. In various embodiments, application software embodying the functionality of the present disclosure can be deployed in different configurations, such as in a client/server arrangement or through a Web browser as a Web-based application or Web service, for example.

Unless defined otherwise, all terms of art, notations and other technical and scientific terms or terminology used herein are intended to have the same meaning as is commonly understood by one of ordinary skill in the art to which the claimed subject matter pertains. In some cases, terms with commonly understood meanings are defined herein for clarity and/or for ready reference, and the inclusion of such definitions herein should not necessarily be construed to represent a substantial difference over what is generally understood in the art.

As used herein, the term “corresponds,” e.g., X corresponds to Y, is intended to mean that X correlates with, or is comparable to, Y. It can mean that X and Y are analogous, or identical, but it is not intended to be limited to this definition. In one example, corresponds is used throughout the description in the context of the virtual product corresponding to the actual product that can be built. This use of the term “corresponds” is intended to mean that the virtual product is similar to the actual product that can be built. The virtual product and the actual product can be the same, or they can have some differences. For example, the virtual product and the actual product may have the same function (e.g., they may both be solar lights), but they may not look identical. This comparison between the virtual product and the actual product would be encompassed by the use of the term “corresponds” herein.

As used herein, the singular forms “a,” “an,” and “the” are intended to include the plural forms as well, unless the context clearly indicates otherwise. It is also to be understood that the term “and/or” as used herein refers to and encompasses any and all possible combinations of one or more of the associated listed items. It is further to be understood that the terms “includes, “including,” “comprises,” and/or “comprising,” when used herein, specify the presence of stated features, integers, steps, operations, elements, components, and/or units but do not preclude the presence or addition of one or more other features, integers, steps, operations, elements, components, units, and/or groups thereof.

The numerical ranges disclosed inherently support any range or value within the disclosed numerical ranges, including the endpoints, even though a precise range limitation is not stated verbatim in the specification because this disclosure can be practiced throughout the disclosed numerical ranges.

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the techniques and their practical applications. Others skilled in the art are thereby enabled to best utilize the techniques and various embodiments with various modifications as are suited to the particular use contemplated.

Although the disclosure and examples have been fully described with reference to the accompanying figures, it is to be noted that various changes and modifications will become apparent to those skilled in the art. Such changes and modifications are to be understood as being included within the scope of the disclosure and examples as defined by the claims.

What is claimed is:

1. A computer-implemented method for generating a virtual product corresponding to an actual product, the method comprising:
graphically displaying a canvas comprising a plurality of parts of the virtual product and one or more tools to build the virtual product, the plurality of parts comprising a housing, a printed circuit board (PCB), a power source, and a plurality of fasteners, wherein each of the plurality of parts and the one or more tools corresponds to actual parts and tools used to build the actual product;
detecting one or more positional user inputs for positioning one or more parts of the plurality of parts on the canvas in relation to one or more other parts of the plurality of parts, wherein the one or more positional user inputs comprises positioning the PCB and the power source within the housing;
detecting one or more fastening user inputs for attaching the one or more parts to the one or more other parts, wherein the one or more fastening user inputs comprises using the one or more tools and one or more fasteners of the plurality of fasteners to attach the PCB and the power source to the housing; and
displaying a generated virtual product on the canvas, wherein the generated virtual product corresponds to the actual product.

2. The computer-implemented method of claim 1, wherein detecting the one or more positional user inputs comprises determining whether the one or more parts is positioned correctly in relation to the one or more other parts.

3. The computer-implemented method of claim 2, wherein, based on a determination that the one or more parts is not positioned correctly in relation to the one or more other parts, the method comprises rejecting attachment of the one or more parts to the one or more other parts.

4. The computer-implemented method of claim 3, wherein rejecting the attachment of the one or more parts to the one or more other parts comprises generating and displaying an indication on the canvas that a position of the one or more parts and/or the one or more other parts is incorrect.

5. The computer-implemented method of claim 3, wherein rejecting the attachment of the one or more parts to the one or more other parts comprises generating and displaying an indication on the canvas including a hint for correctly positioning the one or more parts in relation to the one or more other parts.

6. The computer-implemented method of claim 2, wherein, based on a determination that the one or more parts is positioned correctly in relation to the one or more other parts, the method comprises generating and displaying an indication on the canvas that the one or more parts and one or more other parts are correctly attached.

7. The computer-implemented method of claim 1, comprising generating and transmitting an indication that the virtual product is generated.

8. The computer-implemented method of claim 7, wherein, based on the indication, the method includes causing the actual product to be built.

9. The computer-implemented method of claim 1, wherein the one or more positional user inputs simulate positioning actual parts of the actual product.

10. The computer-implemented method of claim 1, wherein the one or more positional user inputs comprises one or more drag-and-drop inputs on the canvas using a user input device.

11. The computer-implemented method of claim 1, wherein the one or more fastening user inputs simulate fastening actual parts of the actual product with one or more actual fasteners and one or more actual tools.

12. The computer-implemented method of claim 1, wherein the one or more fastening user inputs comprises one or more right-clicking inputs on the canvas using a user input device.

13. The computer-implemented method of claim 1, wherein the plurality of parts comprises one or more wires, and wherein the method comprises detecting one or more connection user inputs for connecting the one or more wires to the PCB and to the power source.

14. The computer-implemented method of claim 13, wherein the one or more connection user inputs simulate connecting one or more actual wires to an actual PCB and to an actual power source.

15. The computer-implemented method of claim 13, wherein the one or more connection user inputs comprises one or more double-clicking inputs on the canvas using a user input device.

16. The computer-implemented method of claim 1, comprising displaying a virtual instruction manual for guiding generation of the virtual product on the canvas, and wherein the method comprises detecting one or more user inputs for navigating of the virtual instruction manual.

17. The computer-implemented method of claim 1, wherein the one or more tools are a cursor on a graphical user interface (GUI) comprising the canvas.

18. The computer-implemented method of claim 1, wherein the power source comprises at least one of a solar panel and a rechargeable battery.

19. A system for generating a virtual product corresponding to an actual product, the system comprising:
a display; and
one or more processors configured to cause the system to:
graphically display, on the display, a canvas comprising a plurality of parts of the virtual product and one or more tools to build the virtual product, the plurality of parts comprising a housing, a printed circuit board (PCB), a power source, and a plurality of fasteners, wherein each of the plurality of parts and the one or more tools corresponds to actual parts and tools used to build the actual product;
detect one or more positional user inputs for positioning one or more parts of the plurality of parts on the canvas in relation to one or more other parts of the plurality of parts, wherein the one or more positional user inputs comprises positioning the PCB and the power source within the housing;
detect one or more fastening user inputs for attaching the one or more parts to the one or more other parts, wherein the one or more fastening user inputs comprises using the one or more tools and one or more fasteners of the plurality of fasteners to attach the PCB and the power source to the housing; and
display, on the display, a generated virtual product on the canvas, wherein the generated virtual product corresponds to the actual product.

20. A non-transitory computer-readable storage medium storing instructions for generating a virtual product corresponding to an actual product, the instructions executable by a system, the system comprising a display and one or more processors, wherein execution of the instructions by the system causes the system to:
graphically display, on the display, a canvas comprising a plurality of parts of the virtual product and one or more tools to build the virtual product, the plurality of parts comprising a housing, a printed circuit board (PCB), a power source, and a plurality of fasteners, wherein each of the plurality of parts and the one or more tools corresponds to actual parts and tools used to build the actual product;
detect one or more positional user inputs for positioning one or more parts of the plurality of parts on the canvas in relation to one or more other parts of the plurality of parts, wherein the one or more positional user inputs comprises positioning the PCB and the power source within the housing;
detect one or more fastening user inputs for attaching the one or more parts to the one or more other parts, wherein the one or more fastening user inputs comprises using the one or more tools and one or more fasteners of the plurality of fasteners to attach the PCB and the power source to the housing; and
display, on the display, a generated virtual product on the canvas, wherein the generated virtual product corresponds to the actual product.
